(19) United States
(12) Patent Application Publication
(10) Pub. No.: US 2002/0127747 A1
(43) Pub. Date: Sep. 12, 2002

(54) Lithography method and apparatus with simplified reticles

(75) Inventors: John George Maltabes, Austin, TX (US); Alain Bernard Charles, Singapore (SG); Karl Emerson Mautz, Round Rock, TX (US)

Correspondence Address: Jim Clingan, Motorola, Inc., Austin Intellectual Property Law Section, 7700 West Parmer Lane, Austin, TX, 78729, US

(73) Assignee: Motorola, Inc.

(21) Appl. No.: 09/801,523

(22) Filed: Mar. 8, 2001

(51) Int. Cl. H01L 21/00; G03F 7/00; G03B 27/32; G03B 27/52; G03B 27/42; G01R 31/26

(52) U.S. Cl. 438/16; 430/313; 430/394; 355/27; 355/53; 29/25.01

(57) ABSTRACT

A lithography method and apparatus is provided for forming at least one semiconductor device on a wafer (12). The method comprises the step, exposing (21) said wafer to an irradiation through a reticle in an exposure tool (4), wherein said exposing (21) includes: at least one mounting step for mounting a first reticle (15) by a mounting device, at least one first exposure step (201), in which said wafer (12) is exposed to said irradiation through said predetermined first reticle (15), at least one change-over step (203) for removing said first reticle (15) and mounting a second predetermined reticle (18) by a change-over device, at least one second exposure step (201), in which said wafer (12) is exposed to said irradiation through said predetermined second reticle (18). In particular a plurality of blade holders may be provided in said exposure tool (4) for protecting a predetermined area on said wafer from a multiple exposure, each blade holder having at least one blade (19) in a frame defining a clear exposure opening of said blade holder. The blade holders may be located either on either side of said reticle (15, 18) or on both sides of said reticle (15, 18).

### FIELD OF THE INVENTION

The present invention generally relates to large scale integration semiconductor devices and in particular, though not exclusively, to a lithography method for forming semiconductor devices with sub-micron structures on a wafer and an apparatus for it.

### BACKGROUND OF THE INVENTION

As device linewidths decrease, many critical level masks can cost upwards of $30,000 to $60,000 to manufacture. Device manufacturing also becomes more complex, so many chip factories build different products with the same manufacturing process. These differences sometimes result in variable amounts of transistors on a chip. Further, it takes a considerable time to manufacture such reticles, e.g. between 3 and 4 months, depending on their complexity.

The present invention seeks to provide a less expensive manufacturing process and apparatus for complex chips which reduces the costs and the time for manufacturing of reticles as compared to the prior art.

### BRIEF DESCRIPTION OF THE DRAWINGS

FIG. 1 illustrates a lithography apparatus according to prior art;

FIG. 2 illustrates schematically a reticle handling system according to an embodiment of the present invention;

FIG. 3 is a flowchart of the lithography for a semiconductor device on a wafer according to prior art; and

FIG. 4 illustrates a sequence of sub-steps as part of a step in FIG. 3 that embody the present invention.

### DETAILED DESCRIPTION OF A PREFERRED EMBODIMENT

The present invention uses a nominal device layout methodology so that all patterns are placed on a uniform grid, and the die size is determined by exposure tool blade settings, and all unnecessary patterns are removed by a less expensive blocking reticle.

This is accomplished by building a reticle at the desired ground rule with all possible positions occupied by the desired features. The blading on the exposure tool is adjusted to include only the various devices desired on the reticle layout, and the wafers are exposed. There are now patterns at all possible locations on the wafer. After a change of reticles, the same wafer is printed with a second exposure that re-exposes in the area where no patterns are desired. Alignment issues are simplified by referring to a zero level mark on the wafer in every exposure step. After developing the remainder of the wafer resist images are only left where they are desired. For a positive resist, the blocking exposure will remove resist. If a negative acting resist is used, large blocks of resist will be left to protect areas where features are not wanted.

This invention supports multiple die sizes and product layouts through the use of inexpensive blocking masks. These masks having no critical geometries or defect requirements should cost in the range of $5,000 to $6,000.

Although the exposure time per wafer in the process according to the invention is longer in comparison to the prior art process, namely by 5 to 6 minutes, the total cycle time is speeded up by the technique according to the invention, as the wait time for new reticles is significantly reduced. The time for the manufacture of the reticles is about 1 to 2 weeks with the present invention instead of 3 to 4 months with the prior art.

Moreover, the blocking mask reticles have an expected manufacturing yield of 100%, while critical level masks generally run at <50% manufacturing yield due to linewidth control variation and defects.

The levels where the technique according to the invention are most useful are gate levels, deep-trench, local interconnect levels and via/contacts, such as in ASICs, fast static RAMs, 4k-, 8k-RAMs, etc.

In the following preferred embodiments of the invention will be described in detail with reference to the accompanying drawings.

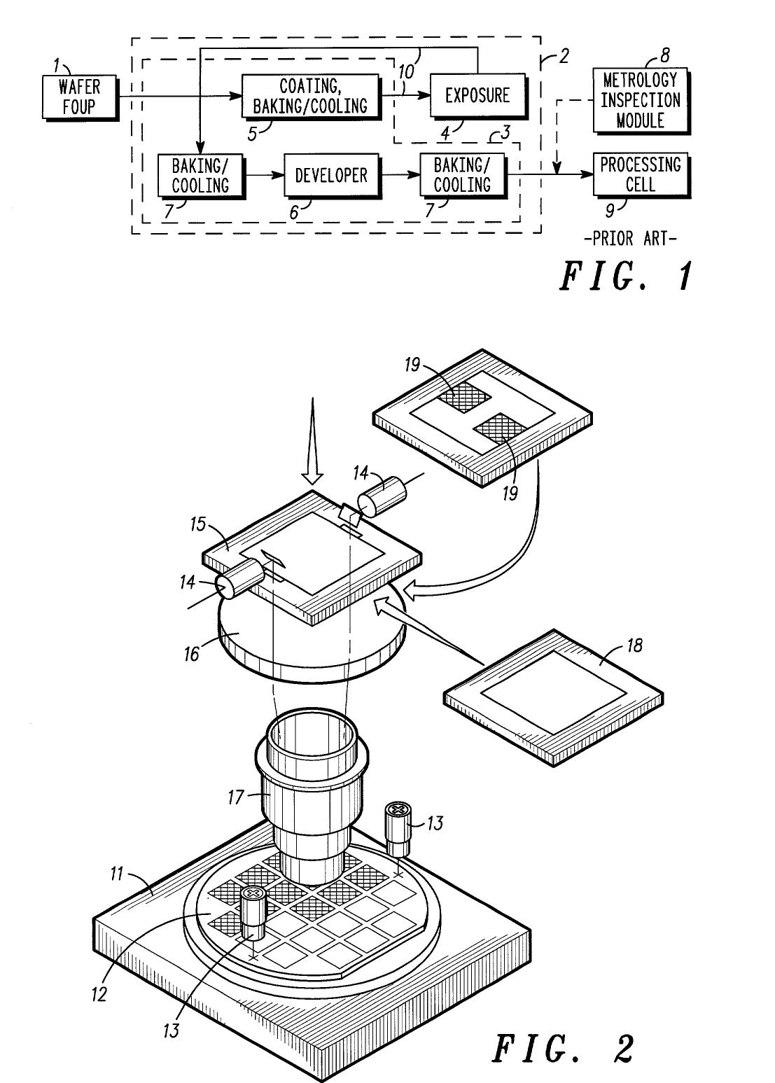

Referring to FIG. 1, there is shown a prior art design of a lithography cell and relevant adjacent tools according to prior art. The wafers to be processed are carried in a Front Opening Unified Pod (FOUP) 1 which contains e.g. 25 wafers of 300 mm diameter each. The wafer FOUP 1 enters into a lithography cell 2 which comprises as main components a coater tool 3 and an exposure tool 4. The lithography cell 2 is indicated by a rectangle with fat lines which encompasses the coater tool 3 and the exposure tool 4 as its components. The coater tool 3 is indicated by a polygon with dashed lines, it comprises a coating means 5, a developer means 6 and a stabilization means 7 for baking/cooling the wafer. (In the following the term “baking” the wafer is meant to include also subsequent “cooling” of the wafer.) After the steps in the lithography cell 2 are completed the wafer is passed on to a processing cell 9 for etching, wet processing or ion implantation. (Although only some specific stabilization steps are explicitly listed above, it should be noted that additional stabilization steps can be provided, such as stabilizing the resist after the coating etc.)

The tools for lithography processing of the wafer are arranged in a loop, and the transportation paths 10 of the wafers between two adjacent processing means are indicated by solid lines (arrows). The wafer first enters the coating means 5 in the coater tool 3, where it is coated with a lithography resist. After coating the wafer is passed on to said exposure tool 4, which is normally external to the coating tool 3 since, concerning the physical environment, the requirements for the exposure parameters and environment are different from the requirements for coating, developing and baking/cooling. In the exposure tool 4 the wafer is exposed to irradiation with light through a reticle. After the exposure in the exposure tool 4 the wafer is returned to the coater tool 3 where it is baked and cooled in order to stabilize the exposed lithography resist on it in a first stabilization means 7. The wafer then enters the developer means 6 in which it is developed and afterwards it is passed on to a second stabilization means 7 for baking the resist pattern on the surface of the wafer. Accordingly, there are multiple wafers concurrently processed at a time: such as one in the coating means 5, being coated with resist, one in the exposure tool 4, being irradiated with light, electrons, ions etc., and one in the developer means 6 or the stabilization means 7. Behind the stabilization means 7 the wafer exits the lithography cell 2 and enters the processing cell 9 for the further processing.

Before the wafer enters the processing cell 9 for further processing, a metrology inspection of the patterns on its surface is carried out, in order to reject wafers with features on their surface that are not properly oriented with respect to the wafer due to a misalignment of the exposed pattern and underlying pattern that was produced during the preceding lithography process or because specific feature sizes have become too small or too large. This metrology inspection is carried out in a separate metrology inspection tool 8, external to the lithography cell 2 and the processing cell 9, respectively.

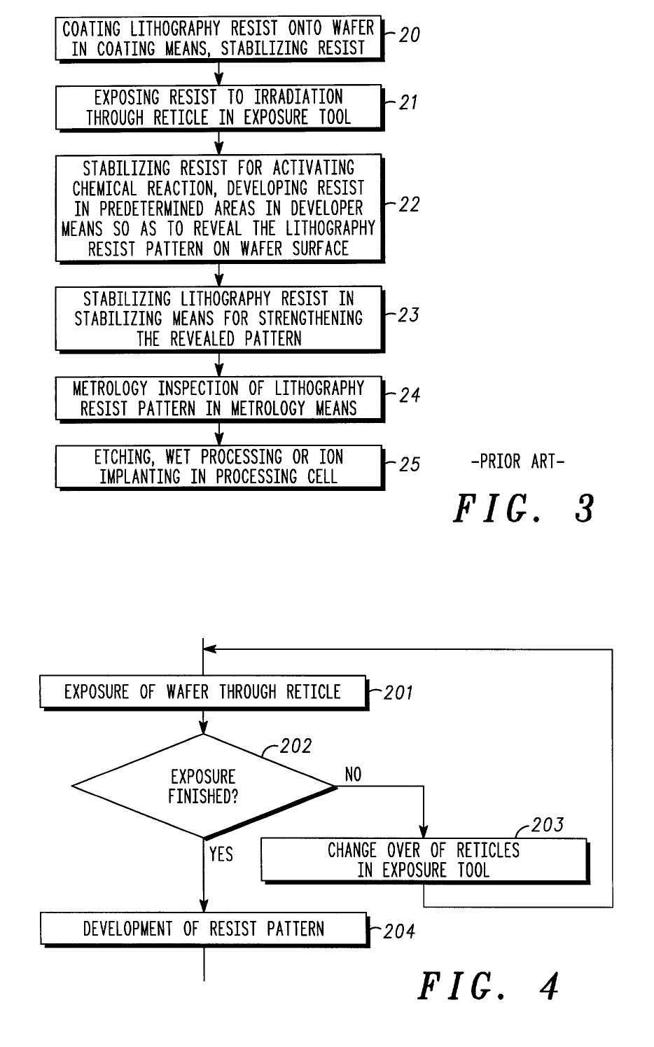

The according steps of the pertaining prior art process are presented in FIG. 3. In an initial step 20 a lithography resist is coated onto the wafer in said coating means 5. Subsequently, at step 21, the wafer with the resist on it is exposed to irradiation with UV light in the exposure tool 4 through a reticle. After exposure the resist is stabilized in a first stabilization means 7 and thereafter it is developed in the developer means 6 at step 22 in order to reveal the pattern on the wafer surface. The developed lithography resist is again stabilized by baking and subsequent cooling in the second stabilization means 7 at step 23 so as to strengthen the pattern on the wafer surface for the following process steps. After the subsequent metrology inspection in the according module 8 at step 24 the batch of wafers is passed on to the processing cell 9. In the processing cell 9 the wafer is etched at step 25, and it is wet processed or ion implanted thereafter (not shown).

However, the more complex the desired device pattern on the semiconductor is, the more complex and costly is the corresponding reticle. Since the time of manufacture of reticles increases exponentially with the complexity of the patterns on it, the complexity of the reticle is reduced according to the invention and the reduced number of features on the wafer after the first exposure is made up for by repeated exposures of the wafer through a plurality of reticles each being of a simpler structure. The principal design of the apparatus for the procedure is schematically illustrated in FIG. 2.

A wafer 12 is fixed on a wafer support 11. By pre-adjustment optics 13 it is ensured that the wafer is properly oriented with respect to a reticle 15 and to an irradiation source (not shown). The radiation (e.g. light) from the irradiation source passes through said reticle 15, which is indicated by a thin arrow in the top of FIG. 2. After the reticle 15 the exposure light passes a focusing lens 16 and an objective 17 which projects the reticle pattern onto said wafer 12. Since the pattern is reduced by the projection, the exact orientation of the wafer with respect to the exposure tool becomes essential, and there are provided further alignment optics 14 for the positioning of the exposed pattern from reticle 15.

Once the exposure of the wafer 12 through said first reticle 15 is finished and a first set of (simple) patterns is defined on the wafer, reticle 15 is removed. It is then replaced by a second reticle 18. Again, the wafer is irradiated through the objective 17, the lens 16 and said reticle 18 in order to define a second set of (simple) patterns on the wafer. A plurality of blades 19 are provided that are placed in front of the reticle 18 from the exposure tool 4 and block parts of the reticle 18 so that desired patterns created by exposure through said first reticle 15 are protected from a second (multiple) irradiation through reticle 18. (Here the term “in front” refers to a position between the light source and the reticle, thus the blade is in front of the reticle when seen from the light source. However, in general blades may be located on both sides of said reticle or on either side of said reticle. Moreover, blades may be used in connection with the first reticle 15 as well as with the second reticle 18 and further reticles.) The blades 19 may be simple opaque sheets of any kind of suited material and of an appropriate shape and they may be mounted in the optical column either as single (moveable) distinct parts or as a fixed arrangement of multiple blades 19 e.g. in a reticle-like frame (cf. FIG. 2). Instead of only a single blade arrangement there may be a plurality of blade holders, each having at least one blade 19 fixedly mounted in a frame defining a clear exposure opening of the blade holder. The appropriate one of the differently shaped blade holders is employed and located in front of said mounting device at a time depending on the first and the second reticle 15 and 18, respectively, so as to position at least one blade 19 in front of said reticle 18 when exposing the wafer. Thus a predetermined area on said wafer is protected from multiple exposures. (It is clear that if there are blades or blade holders on both sides of the reticle each of the blades or blade holders may be of different size and shape. In this case the area on the wafer that is blocked off by the arrangement of blades or blade holders on both sides of the reticle is the combination of the two areas that are blocked off by a single one of the blades or blade holders.)

The plurality of blade holders may either be mounted fixedly in said exposure tool 4 as a cluster of available blade holders. When the exposure reticles 15 and 18, respectively, are changed the appropriate one of the blade holders is moved from a standby position internal of the optical column into an operating position. However, the blade holders may also be supplied from outside of the optical column. (In FIG. 2, for sake of clarity, only one kind of blades 19 is shown the shape of which is chosen to be a rectangle.) The positioning of the blades 19 in front of the second reticle 18 is indicated by an arrow pointing from the frame with the blades 19 to the optical column in the exposure tool 4. Thus only patterns of reticle 18 that are not bladed off by blades 19 are transferred to specific areas on the wafer. If necessary, the exact orientation of the reticle 18 and the wafer 12 with respect to each other has to be confirmed again. If so, the alignment procedure has to be repeated on the basis of the results from the alignment optics 14. This procedure may refer to the alignment marks on the wafer 12, as well for reticle 15 as for reticle 18. The change of reticles is indicated by a second arrow in FIG. 2 pointing from the second reticle 18 to the first reticle 15.

In another preferred embodiment (not shown) there is only one blade 19 positioned in front of said reticle 18 having the form of an iris diaphragm with an adjustable open radius. The radius of the iris that defines the clear exposure opening of the blade holder is adjusted in accordance with the requirements as to the areas to be irradiated on the wafer. The blade holder having the form of an iris diaphragm is preferably mounted fixedly in the optical column.

The corresponding sequence of processing steps is illustrated in FIG. 4. In step 201 the wafer 12 is exposed to radiation through a first reticle 15. In step 202 it is examined whether or not the wafer is to be exposed by a second reticle to create additional features on the wafer surface. If additional features are desired on the wafer the present reticle is removed in step 203, and it is replaced by another reticle 18. This loop of processing steps is repeated as long as there are features to be defined on the wafer surface. Once the definition of patterns on the wafer is completed the resist pattern on the wafer surface is developed (step 204) and the processing is continued as known in the art.

It should be noted that not only can patterns be added to already existing features on the wafer by repeated exposure steps, but that also created patterns can be deleted by exposing the wafer to irradiation and blocking those areas on the wafer which have been defined in previous steps and which are to remain.

While the invention has been described in terms of particular structures, devices and methods, those of skill in the art will understand based on the description herein that it is not limited merely to such examples and that the full scope of the invention is properly determined by the claims that follow.

1. A lithography method for forming at least one semiconductor device on a wafer including the steps of:
coating a lithography resist onto said wafer in a coating means,
exposing said wafer to an irradiation through a reticle in an exposure tool,
stabilizing said lithography resist for activating chemical reaction and developing said lithography resist in said predetermined areas in a developer means so as to reveal a predetermined lithography resist pattern on the wafer surface,
stabilizing the lithography resist in a stabilization means for strengthening said pattern on the wafer surface,
performing a metrology inspection of said lithography resist pattern on said wafer surface in a metrology tool,
etching, wet processing or implanting ions into said wafer in a processing cell,
wherein said exposing includes:
at least one mounting step for mounting a first reticle by a mounting device,
at least one first exposure step, in which said wafer is exposed to said irradiation through said predetermined first reticle,
at least one change-over step for removing said first reticle and mounting a second predetermined reticle by a change-over device,
at least one second exposure step, in which said wafer is exposed to said irradiation through said predetermined second reticle.

2. Method according to claim 1, wherein reticle blades are adjusted before said second reticle so as to protect predetermined areas on the wafer that are already exposed of a second irradiation.

3. A lithography apparatus for forming at least one semiconductor device on a wafer having a lithography cell, a metrology tool for performing a metrology inspection of said wafer, and a processing cell for etching, wet processing or ion implantation into said wafer, said lithography cell comprising:
coating means for coating a lithography resist onto said wafer,
an exposure tool for exposing said wafer to an irradiation through a reticle,
stabilizing means for stabilizing said lithography resist for activating chemical reaction,
developer means for developing said lithography resist in said predetermined areas so as to reveal a predetermined lithography resist pattern on the wafer surface,
stabilization means for stabilizing the lithography resist for strengthening said pattern on the wafer surface,
wherein said exposure tool comprises:
a mounting device for mounting a plurality of reticles,
a change-over device for removing a first of said plurality of reticles and mounting a second of said plurality of reticles.

4. The lithography apparatus according to claim 3,
comprising a plurality of blade holders, each having at least one blade fixedly mounted in a frame defining a clear exposure opening of said blade holder, wherein at least one of said plurality of blade holders is located between a light source and said wafer so as to protect a predetermined area on said wafer from a multiple exposure.

5. The lithography apparatus according to claim 4,
wherein said plurality of blade holders is mounted moveably in said exposure tool.

6. The lithography apparatus according to claim 3,
wherein a blade having the form of an iris diaphragm with adjustable open radius is positioned in front of said reticle.
